(19) United States
(12) Patent Application Publication
(10) Pub. No.: US 2019/0103474 A1
(43) Pub. Date: Apr. 4, 2019

(54) SIDEWALL ENGINEERING FOR ENHANCED DEVICE PERFORMANCE IN ADVANCED DEVICES

(71) Applicant: GLOBALFOUNDRIES Singapore Pte. Ltd., Singapore (SG)

(72) Inventors: Eng Huat TOH, Singapore (SG); Shyue Seng TAN, Singapore (SG); Kiok Boone Elgin QUEK, Singapore (SG)

(21) Appl. No.: 15/724,230

(22) Filed: Oct. 3, 2017

(51) Int. Cl. H01L 29/66; H01L 29/49; H01L 29/78

(52) U.S. Cl. CPC H01L 29/6656; H01L 29/7833; H01L 29/4983; H01L 29/66598

(57) ABSTRACT

A method of sidewall engineering with negative capacitance materials is disclosed. For example, the negative capacitance material is a ferroelectric material. The method includes providing a dielectric liner on the sidewall of the gate and providing a negative capacitance liner or spacer over the dielectric liner. In one embodiment, the dielectric liner is an oxide liner and the negative capacitance liner or spacer is a ferroelectric liner or spacer. The engineered negative capacitance liner or spacer enhances the gate-to-S/D region and gate-to-contact coupling and hence the device I_{ON}-I_{OFF} performance is improved.

### BACKGROUND

Transistors are important components in integrated circuits (ICs). A transistor includes a gate between first and second source/drain (S/D) regions. The channel of a transistor is located under the gate between the S/D regions. The length of the transistor channel is the distance between the S/D terminals. Advances in processing technology continue to facilitate scaling of devices, resulting in smaller and smaller transistors. An advantage of scaling is the improvement of speed due to shorter channel lengths. Scaling also reduces cost by increasing the number of components per given area.

However, as the channel length reaches a lower limit, the off-state leakage current I_{off} and the on-state driving current Iₒₙ are negatively affected. For example, I_{off} is high and Iₒₙ is low. This negatively affects the performance of a transistor.

The present disclosure is directed to a transistor with improved I_{off}-Iₒₙ performance.

### SUMMARY

In one embodiment, a device is disclosed. The device includes a substrate having a device region, a gate stack and first and second source/drain (S/D) regions disposed in the device region. The device further includes one or more spacer units, wherein the one or more spacer units includes a first dielectric spacer liner deposited on sidewalls of the gate stack, and a second negative capacitance spacer liner or layer disposed on the first dielectric spacer liner, wherein the negative capacitance spacer liner or layer enhances gate-to-S/D region coupling.

In another embodiment, a method of forming a device is presented. The method includes forming a device includes forming a substrate with a device region and forming a gate stack and first and second source/drain (S/D) regions in the device region. The method further includes forming one or more spacer units, wherein the one or more spacer units comprise a first dielectric spacer liner deposited on sidewalls of the gate stack, and a second negative capacitance spacer liner or layer disposed on the first dielectric spacer liner, wherein the negative capacitance spacer liner or layer enhances gate-to-S/D region coupling.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows a schematic diagram of an embodiment of a device;

FIGS. 2a-b show a cross-sectional view of an embodiment of a device and the associated parasitic capacitance model of the device;

FIGS. 2c-d show a cross-sectional view of another embodiment of a device and the associated parasitic capacitance model of the device;

FIG. 2e shows a simplified 3-dimensional (3D) view of an embodiment of a device; and

FIGS. 3a-h show cross-sectional views of an embodiment of a process of forming a device.

### DETAILED DESCRIPTION

Embodiments generally relate to semiconductor devices. More particularly, some embodiments relate to semiconductor devices having transistors with engineered gate sidewalls. The engineered gate sidewalls, for example, include a negative capacitance liner. The negative capacitance liner, for example, is a ferroelectric liner.

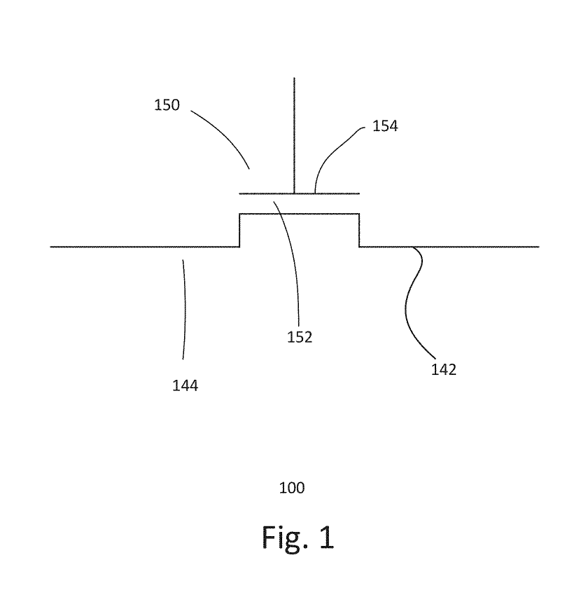

FIG. 1 shows a schematic diagram of an embodiment of a device 100. The device includes a transistor, such as a metal-oxide-semiconductor (MOS) field effect transistor (FET). The transistor may include various types of junctions, such as transistors with overlapping or underlapping S/D junctions. Overlapping junctions refer to junctions which reach or are slightly under the gate while underlapping junctions refers to junctions which do not reach the gate. The transistor may also include junctionless transistors. A junctionless transistor refers to a transistor without any junctions. For example, the source, channel and drain regions of the transistor includes a single dopant type. The transistors may include other types of transistors, such as fin field effect transistors (finFETs) as well as nano-wire transistors. Other types of transistors may also be useful.

As shown, the transistor includes a gate 150 disposed between first and second S/D terminals 142 and 144. The transistor may be disposed on a substrate. The substrate may be a bulk semiconductor substrate, such as a silicon substrate, or a crystalline-on-insulator (COI) substrate, such as a silicon-on-insulator (SOI) substrate. Other types of bulk or COI substrates may also be useful. The gate includes a gate electrode 154 and a gate dielectric 152. The gate may be a metal gate. For example, the gate includes a metal gate electrode and a high k gate dielectric. Other types of gates may also be useful. The gate electrode is disposed above the gate dielectric. As for the S/D regions, they may be elevated S/D regions disposed above the substrate. Other types of S/D regions may also be useful. The S/D regions may be heavily doped regions with first polarity type dopants.

Lightly doped (LD) extension regions may be disposed in the substrate below. The LD extension regions are lightly doped regions with first polarity type dopants. The LD extension regions may be overlapping or underlapping LD extension regions. In some embodiments, no LD extension regions are provided. A channel below the gate and between the S/D regions may be doped with second polarity type dopants. For example, a S/D region may include both a heavily doped S/D region and a LD extension region.

The first S/D region serves as a first S/D terminal, the second S/D region serves as a second S/D terminal, and the gate serves as a gate terminal. The substrate below the gate serves as a channel of the transistor. The channel may be doped with second polarity type dopants. The length of the channel may be equal to about a length of the gate in contact with the gate dielectric.

In other embodiments, the transistor may be a junctionless transistor. In the case of a junctionless transistor, the S/D regions and the channel under the gate have the same dopant type. For example, the S/D regions and the channel may be doped with first polarity type dopants with the same dopant concentration. For example, no dopant gradient exists between the S/D regions and the channel. In some embodiments, a dopant gradient profile may be formed between the S/D regions and the channel. For example, the S/D regions may be heavily n-doped while the channel may be lightly or intermediately n-doped. The S/D regions and channel may be heavily doped with first polarity type dopants. For example, the S/D regions and channel may be heavily doped n-type regions for a n-type junctionless transistor. Doping the S/D regions and channel with other dopant concentrations or dopant types may also be useful.

In one embodiment, the gate includes sidewall spacer units disposed on the sidewalls of the gates adjacent to the first and second S/D regions. The sidewall spacer units are composite spacer units which include multiple spacer layers. In one embodiment, a composite sidewall spacer unit includes a ferroelectric sidewall layer which is separated from the gate sidewalls by a dielectric liner. The dielectric liner may be an oxide liner. Other types of dielectric liners may also be useful. The ferroelectric sidewall is disposed on the dielectric liner. In some embodiments, the ferroelectric layer may be a ferroelectric liner disposed on the dielectric liner. A dielectric spacer may be disposed on the ferroelectric liner. The dielectric spacer may be an oxide, a nitride or an oxynitride spacer. Other configurations of sidewall spacer units with a ferroelectric layer may also be useful. For example, a ferroelectric spacer may be disposed over a dielectric liner, such as an oxide liner.

In one embodiment, the ferroelectric layer of a sidewall spacer unit extends the height of the gate. For example, a ferroelectric liner or spacer layer may extend the height of the gate. Alternatively, the ferroelectric layer may extend a partial height of the gate. For example, a ferroelectric spacer may extend a partial height of the gate, such as half the height of the gate. Other configurations of the ferroelectric sidewall liners or spacer layers may also be useful. The ferroelectric sidewall layer may be a hafnium-zirconium oxide (HfZrOₓ). Other types of ferroelectric sidewall layers, such as barium-titanium oxide (BaTiO₃) or doped hafnium oxide (HfO₂), may also be useful. Doped hafnium oxide may include tetragonal HfO₂, such as Si:HfO₂, or tetragonal hafnium oxide, such as Al:HfO₂.

As described, each of the spacer units includes a ferroelectric spacer layer. The ferroelectric spacer layer is configured to provide negative capacitance. This amplifies coupling to S/D extension regions, which extend the effective length L_{eff} of the channel of the transistor in the off-state. Extending L_{eff} improves the Iₒₙ-I_{off} performance. In some embodiments, reduced gate to contact capacitance is to improve AC performance.

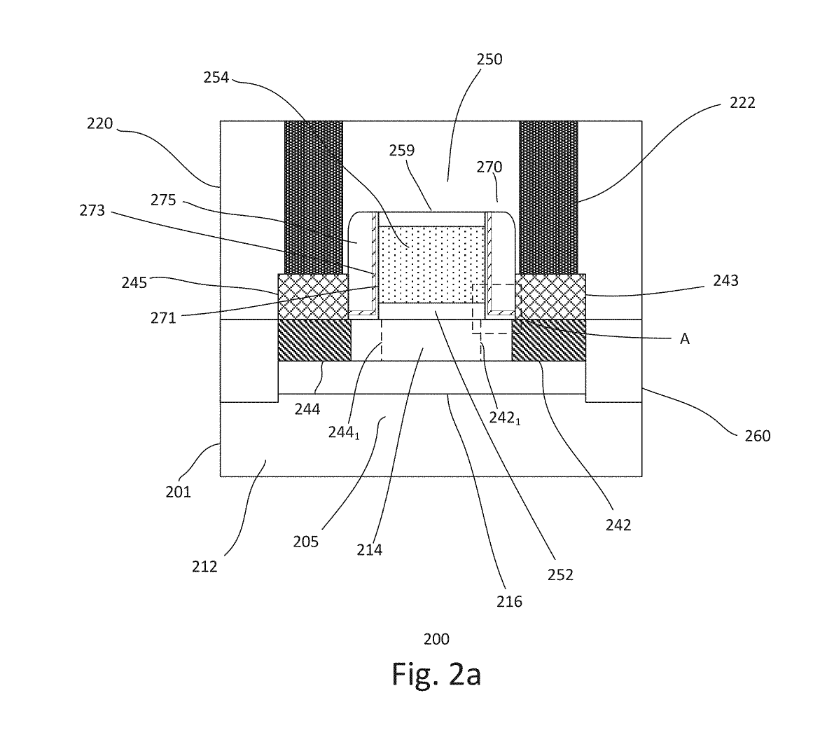

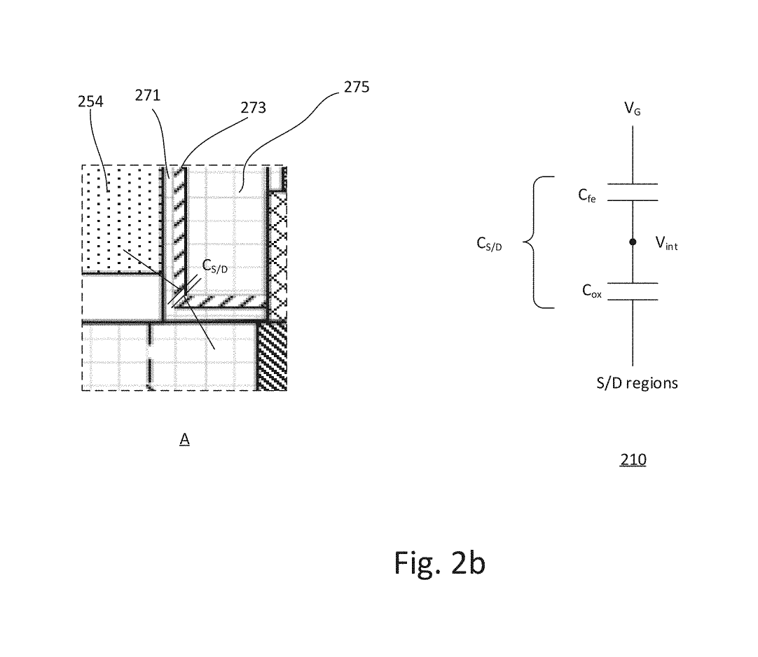

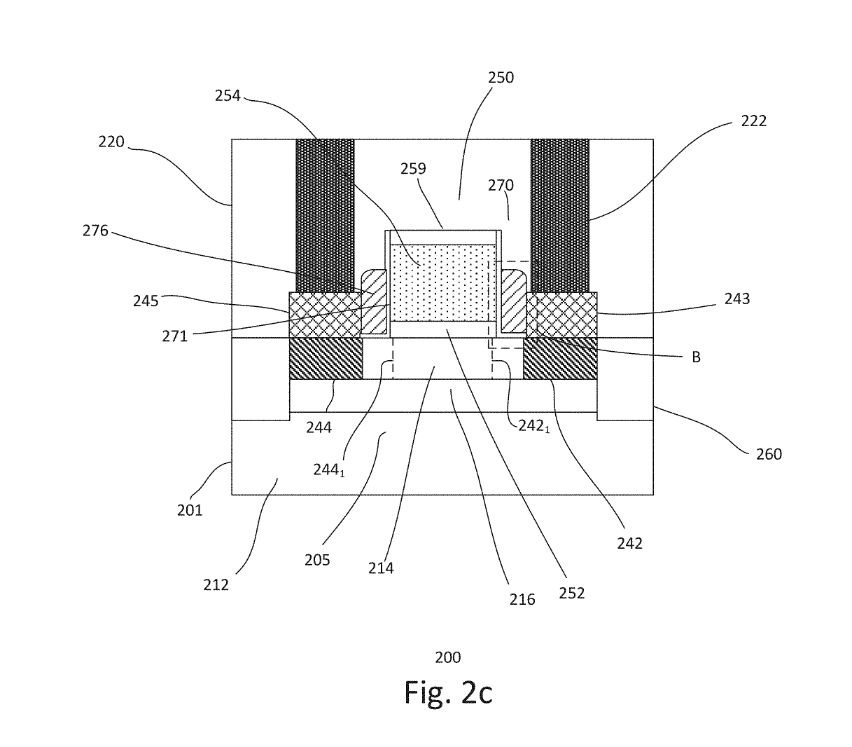

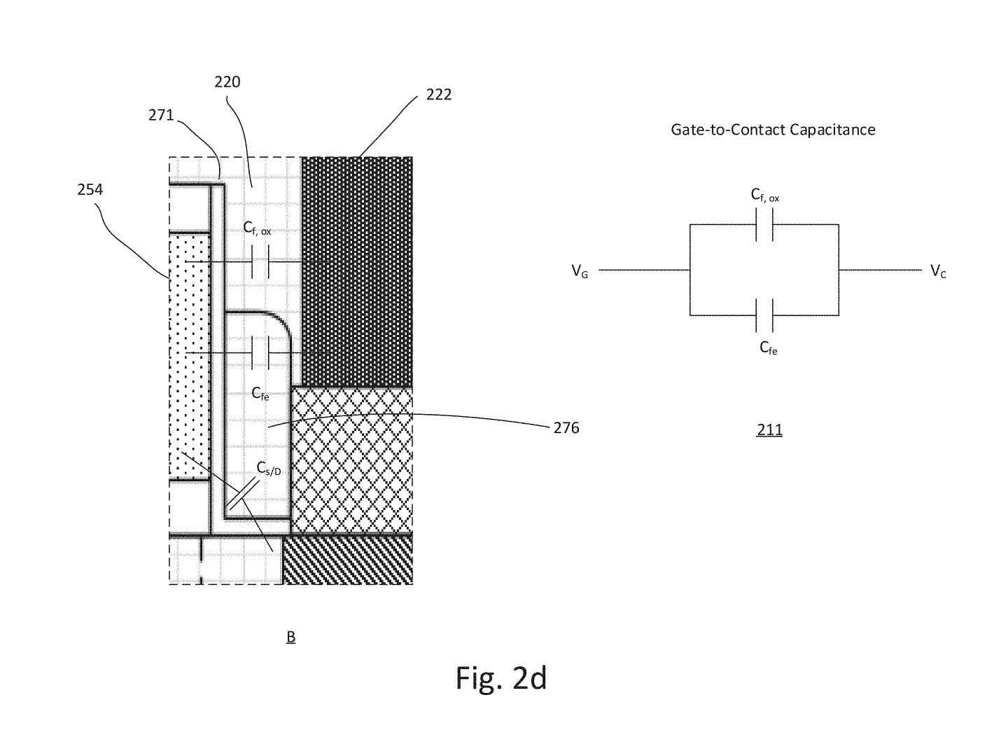

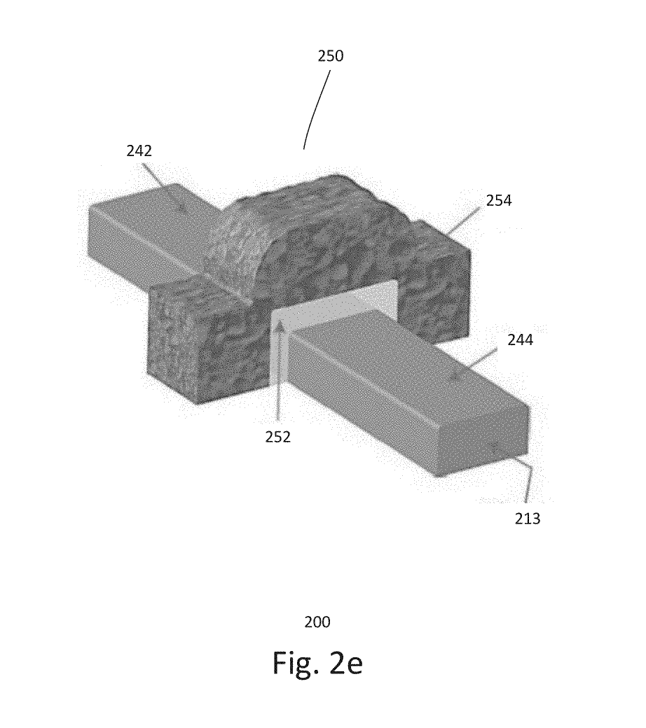

FIGS. 2a-b show a cross-sectional view of an embodiment of a device 200, a close up view of A and the associated parasitic capacitance model 210. The device, for example, is an integrated circuit (IC). As shown, the device includes a transistor. The transistor is similar to the transistor described in FIG. 1. Common elements may not be described or described in detail.

The device may include doped regions having different dopant concentrations. For example, the device may include heavily doped (x⁺), intermediately doped (x) and lightly doped (x⁻) regions, where x is the polarity type which can be p or n. A lightly doped region may have a dopant concentration of about 10¹⁶ to 10¹⁷ cm⁻³, an intermediately doped region may have a dopant concentration of about 10¹⁸ to 10¹⁹ cm⁻³, and a heavily doped region may have a dopant concentration of about 10²⁰ to 10²¹ cm⁻³. The doping concentrations, for example, are for 55 nm technology node. Providing other dopant concentrations for different doped regions may also be useful. For example, dopant concentrations may vary depending on, for example, the technology node. P-type dopants may include boron (B), aluminum (Al), indium (In) or a combination thereof, while n-type dopants may include phosphorous (P), arsenic (As), antimony (Sb) or a combination thereof.

The transistor is disposed in a device region of a substrate 201. The substrate, as shown, is a COI substrate, such as a SOI substrate. Other types of substrates, such as bulk (non-COI) substrates, may also be useful. The SOI substrate includes a buried insulator layer 216, such as silicon oxide, disposed between a bulk silicon layer 212 and a surface silicon layer 214. Other types of crystalline layers or buried insulators layer may also be useful. The thickness of the buried insulator layer may be about 5-200 nm while the thickness of the surface silicon or crystalline layer may be about 2-200 nm. Other thicknesses for the buried insulator and the surface crystalline layer may also be useful.

In other embodiments, the substrate may be a bulk semiconductor substrate, such as a silicon substrate. Other types of bulk semiconductor substrates may also be useful. The surface substrate may be a lightly doped substrate, such as a lightly doped p-type substrate. Providing a substrate with other types of dopants or dopant concentrations as well as an undoped substrate, may also be useful.

The device regions may be a low voltage (LV) device region for a LV metal oxide semiconductor (MOS) transistor, a medium voltage (MV) device region for a MV MOS transistor or a high voltage (HV) device region for a HV MOS transistor. Other device regions may also be provided on the substrate. Although the substrate is shown with one device region, it is understood that the substrate may include other device regions for other types of devices, including a memory region for memory cells.

A device isolation region 260 is provided. The isolation region surrounds the device region. The isolation region isolates the cell region from other device regions. Other isolation regions may also be provided to isolate other device regions. The isolation region may be a shallow trench isolation (STI) region. A STI region includes an isolation trench filled with isolation or dielectric materials. In the case of a COI substrate, the STI region extends slightly below the bottom of the surface substrate in the buried oxide layer. Other types of isolation regions may also be employed, depending on the application.

In one embodiment, a device well 205 is disposed in the surface substrate of the device region. In one embodiment, the device well is disposed within the device isolation region. In one embodiment, the depth or bottom of the device well extends the thickness of the surface substrate. Providing a device well having other depths may also be useful. Other configuration of device wells may also be useful. The device well includes second polarity dopants for a first polarity type transistor. For example, a device well includes p-type dopants for a n-type transistor or n-type dopants for a p-type transistor. The device well may be lightly (x⁻) or intermediately (x) doped with second polarity type dopants. Other dopant concentration may also be useful for the cell well.

The transistor includes a gate 250 disposed on a substrate between first and second S/D regions 243 and 245. The gate includes a gate electrode 254 disposed over a gate dielectric 252. The gate dielectric is disposed on the substrate. The gate may be a metal gate. For example, the gate includes a metal gate electrode disposed over a high k gate dielectric. Other types of gate electrodes and gate dielectrics may also be useful. The thickness of the gate electrode may be about 20-100 nm and the thickness of the gate dielectric may be about 1-20 nm. Other thicknesses for the gate electrode and gate dielectric may also be useful, depending on the application. The gate includes sidewall spacer units 270 disposed on first and second gate sidewalls adjacent to the first and second S/D regions.

As for the S/D regions 243 and 245, they may be elevated S/D regions. Elevated S/D regions are disposed on epitaxial S/D layers formed over the surface of the substrate in the device region. In one embodiment, the epitaxial S/D layers are selective epitaxial grown (SEG) layers which are selectively disposed over the substrate in the device region adjacent to the sidewall spacer units. The epitaxial S/D layers are heavily doped with first polarity type dopants. The epitaxial S/D layers may be doped by ion implantation or in-situ doping. The thickness of the elevated S/D regions may be about 10-50 nm above the surface of the substrate. Other thicknesses may also be useful. In other embodiments, non-elevated S/D regions may be used.

In some embodiments, first and second lightly doped (LD) extension regions 242 and 244 may be provided in the surface crystalline layer below the first and second S/D regions. The LD extension regions, in one embodiment, extend the thickness of the surface crystalline layer. The LD extension regions are lightly doped with first polarity type dopants. For example, the LD extension and S/D regions are doped with the same polarity type dopants, with the LD extension regions being lightly doped while the S/D regions are heavily doped.

The LD extension regions 242₁ and 244₁ may be underlapping or overlapping LD extension regions. In the case of underlapping LD extension regions, adjacent edges extend slightly under the spacer unit. In the case of overlapping LD extension regions, adjacent edges of the LD extension regions extend slightly under the gate, as indicated by dotted lines.

The S/D regions serve as S/D transistor terminals and the gate serves as a gate terminal of the transistor. The S/D regions and gate electrode may include metal silicide contacts, such as nickel-based silicide contacts. Other types of metal silicide contacts may also be useful. In other embodiments, the transistor may be a junctionless transistor. In the case of a junctionless transistor, the S/D regions and the channel under the gate have the same dopant type. For example, the S/D regions and the channel may be doped with first polarity type dopants with the same dopant concentration. For example, no dopant gradient exists between the S/D regions and the channel. In some embodiments, a dopant gradient profile may be formed between the S/D regions and the channel. For example, the S/D regions may be heavily n-doped while the channel may be lightly or intermediately n-doped. The S/D regions and channel may be heavily doped with first polarity type dopants. In some cases, the device well may be heavily doped with first polarity type dopants, serving as S/D regions and the channel. The S/D regions and channel may be heavily doped n-type regions for a n-type junctionless transistor. Doping the S/D regions and channel with other dopant concentrations or dopant types may also be useful.

An inter-layer dielectric layer 220 is disposed over the substrate, covering the substrate and the gate stack. The inter-layer dielectric layer may be a silicon oxide layer formed by chemical vapor deposition (CVD). Other types of dielectric layers may also be useful. The inter-layer dielectric layer, for example, serves as the first contact level of a BEOL dielectric layer having a plurality of ILD levels. An ILD level includes a contact or via dielectric layer below a metal level dielectric layer. Contacts are disposed in the inter-layer dielectric layer and metal lines are disposed in the metal level dielectric layer. As shown, contacts 222 are disposed in the inter-layer dielectric layer. The contacts are coupled to the S/D regions and gate terminals.

Regarding the spacer units, each includes a ferroelectric layer. The ferroelectric layer is separated from a gate sidewall by a dielectric layer, such as an oxide layer. In one embodiment, a spacer unit includes a first spacer liner 271, a second negative capacitance spacer liner 273 and a spacer 275. The first liner may be an oxide liner, the second negative capacitance liner may be a ferroelectric liner 273 and the spacer is a dielectric layer, such as oxide, nitride or combination of oxide and nitride. The ferroelectric liner may be a hafnium-zirconium oxide (HfSiOₓ) liner. Other types of ferroelectric liners, such as barium-titanium oxide (BaTiO₃) or doped hafnium oxide (HfO₂) liners, may also be useful. Doped hafnium oxide may include tetragonal HfO₂, such as Si:HfO₂, or tetragonal hafnium oxide, such as Al:HfO₂. The first and second liners, as shown, are L-shaped liners while the spacer occupies the space created by the L-shaped liners. For example, the spacer has an outer edge which is aligned with an outer edge of the L-shaped spacer liners. Other configurations of spacer units may also be useful.

The parasitic capacitance model of the transistor is shown in FIG. 2b. The parasitic capacitance model includes a parasitic capacitance Cₑₓₜ produced by the spacer unit. The capacitance Cₑₓₜ is the gate-to-S/D region capacitance. As shown, the capacitance Cₑₓₜ includes the parasitic capacitance C_{fe} produced by the ferroelectric liner and the parasitic capacitance Cₒₓ produced by the oxide liner disposed between the gate and the S/D regions in the surface substrate. The voltage at the gate is V_{G} and the voltage node between C_{fe} and Cₒₓ is Vᵢₙₜ. Based on the divider rule, the value Vᵢₙₜ is defined by Equation 1 below:

$${V}_{int} = {V}_{G} * \frac{{C}_{fe}}{{C}_{fe} + {C}_{ox}} ; \qquad ( Equation 1 ) ;$$

and where
V_{G} is the voltage at the gate terminal.
   From equation 1, it can be seen that if C_{fe} is negative, then Vᵢₙₜ will be greater than V_{G}. In one embodiment, |C_{fe}|>|Cₒₓ| so that C_{fe}+Cₒₓ<0. As a result,

$$\frac{{C}_{fe}}{{C}_{fe} + {C}_{ox}} > 0$$

and an overall positive parasitic capacitance is achieved. As for the thickness of the ferroelectric liner, in one embodiment, the thickness of the ferroelectric liner may be tailored to ensure that

$$\frac{{C}_{fe}}{{C}_{fe} + {C}_{ox}} > 1.$$

The thickness may depend on the ferroelectric material and its capacitance.

As described, a spacer unit includes a ferroelectric liner separated from a gate sidewall by a dielectric liner, such as an oxide liner. The ferroelectric liner is configured to provide a negative capacitance. This achieves a high gate-to-S/D region coupling which results in voltage amplification. The ferroelectric liner amplifies the coupling to the S/D region. This extends L_{eff} in the off-state and increases source potential barrier reduction in on-state. As a result, the I_{ON}-I_{OFF} performance of the device is improved.

FIGS. 2c-d show a cross-sectional view of another embodiment of a device 200, a close up view of B and the associated parasitic capacitance model 211. The device, for example, is an integrated circuit (IC). As shown, the device includes a transistor. The transistor is similar to the transistor described in FIG. 1 and FIGS. 2a-b. Common elements may not be described or described in detail.

The transistor is disposed in a device region of a substrate 201. The substrate, as shown, is a COI substrate, such as a SOI substrate, with a buried insulator layer 216 disposed between a bulk crystalline layer 212 and a surface crystalline layer 214. Other types of substrates, such as a bulk substrate, may also be useful.

A device isolation region 260, such as a STI region, is provided. Other types of isolation regions may also be useful. The isolation region surrounds the device region. The isolation region isolates the cell region from other device regions. Other isolation regions may also be provided to isolate other device regions.

A device well 205 is disposed in the substrate. In one embodiment, a device well is disposed in the surface substrate of the device isolation region. The device well includes second polarity dopants for a first polarity type transistor. The transistor includes a gate 250 disposed on a substrate between first and second S/D regions 243 and 245. The gate includes a gate electrode 254 disposed over a gate dielectric 252. The gate includes sidewall spacer units 270 disposed on first and second gate sidewalls adjacent to the first and second S/D regions.

As for the S/D regions, they may be elevated S/D regions. Elevated S/D regions may be disposed on epitaxial S/D layers formed over the surface of the substrate in the device region. Non-elevated S/D regions may also be useful. First and second lightly doped (LD) extension regions 242 and 244 may be provided in the surface crystalline layer below the first and second S/D regions. The LD extension regions may be underlapping or overlapping LD extension regions. Providing S/D regions without LD regions may also be useful.

In other embodiments, the transistor may be a junctionless transistor. In the case of a junctionless transistor, the S/D regions and the channel under the gate have the same dopant type. For example, the S/D regions and the channel may be doped with first polarity type dopants with the same dopant concentration. For example, no dopant gradient exists between the S/D regions and the channel. In some embodiments, a dopant gradient profile may be formed between the S/D regions and the channel. For example, the S/D regions may be heavily n-doped while the channel may be lightly or intermediately n-doped. The S/D regions and channel may be heavily doped with first polarity type dopants. In some cases, the device well may be heavily doped with first polarity type dopants, serving as S/D regions and the channel. The S/D regions and channel may be heavily doped n-type regions for a n-type junctionless transistor. Doping the S/D regions and channel with other dopant concentrations or dopant types may also be useful.

An inter-layer dielectric layer 220 is disposed over the substrate, covering the substrate and gate stack. The inter-layer dielectric layer may be a silicon oxide layer formed by chemical vapor deposition (CVD). Other types of dielectric layers may also be useful. The inter-layer dielectric layer, for example, serves as the first contact level of a BEOL dielectric layer having a plurality of ILD levels. An ILD level includes a contact or via dielectric layer below a metal level dielectric layer. Contacts are disposed in the inter-layer dielectric layer and metal lines are disposed in the metal level dielectric layer. As shown, contacts 222 are disposed in the inter-layer dielectric layer. The contacts are coupled to the S/D regions and gate terminals.

Regarding the spacer units, each includes a ferroelectric spacer. The ferroelectric spacer is separated from the gate sidewall by a dielectric liner, such as an oxide layer. In one embodiment, the spacer unit includes a spacer liner 271 and a negative capacitance spacer 276. The spacer liner is an oxide liner. The negative capacitance spacer, in one embodiment is a ferroelectric spacer. The ferroelectric spacer may be a hafnium-zirconium oxide (HfZrOₓ) liner. Other types of ferroelectric spacers, such as barium-titanium oxide (BaTiO₃) or doped hafnium oxide (HfO₂) spacers, may also be useful. Doped hafnium oxide may include tetragonal HfO₂, such as Si:HfO₂, or tetragonal hafnium oxide, such as Al:HfO₂. The spacer liner is an L-shaped liner while the spacer occupies the space created by the L-shaped liners. In one embodiment, the ferroelectric spacers are recessed below the top surface of the gate. The ferroelectric spacers may be disposed above the elevated S/D regions but below the top surface of the gate.

As described, a spacer unit includes a ferroelectric spacer separated form a gate sidewall by a dielectric liner, such as an oxide liner. In addition, the upper portion of the gate above the ferroelectric spacer includes the first inter-layer dielectric layer, such as silicon oxide. The ferroelectric spacer is configured to provide negative capacitance.

The parasitic capacitance model of the transistor is shown in FIG. 2d. The parasitic capacitance model includes a parasitic capacitance C_{f, ox} produced by the inter-layer dielectric layer between the gate and the contact, a parasitic capacitance C_{fe} produced by the ferroelectric spacer between the gate and the contact. The parasitic capacitance C_{f, ox} and C_{fe} are coupled in parallel between the gate and contact. The effective gate-to-contact capacitance is measured between the gate and the contact using the Equation (2) below:

C_{eff}=C_{fe}+C_{f,ox} Equation (2).

From Equation 2, C_{eff} can be reduced when C_{fe}<0 and |C_{fe}|<|C_{f,ox}|. The negative capacitance spacer reduces the effective gate-to-contact capacitance and thus the AC performance is improved. The thickness and height of the ferroelectric spacer can be tailored to achieve the desired C_{eff}. For example, the thickness and height of the ferroelectric spacer can be tailored to satisfy, for example, C_{fe}+C_{f,ox}>0. The thickness and height may depend on the ferroelectric material used.

In addition, parasitic capacitance Cₑₓₜ is also produced by C_{fe} and Cₒₓ, as described in FIGS. 2a-b. For example, Cₑₓₜ is also produced by C_{fe} and Cₒₓ based on Equation 1, as described with respect to FIG. 2b. The ferroelectric spacer is configured to provide a negative capacitance. This achieves a high gate-to-S/D region coupling which results in voltage amplification. The ferroelectric spacer amplifies the coupling to the S/D region. This extends L_{eff} in the off-state and increases source potential barrier reduction in the on-state. As a result, the I_{ON}-I_{OFF} performance of the device is improved.

As described, the transistors of FIGS. 2a-d are described with COI substrates. In other embodiments, the transistors may be disposed on bulk semiconductor crystalline substrates, such as silicon. Other types of bulk substrates may also be useful. In bulk application, the depth of LD extension regions, device well and STI region are not limited by the depth of the surface substrate of a COI substrate. For example, a device well may have a depth greater than a STI region, with the LD extensions shallower than the depth of the STI regions. Other configurations of the device well, STI regions and LD extension regions may also be useful. In addition, a deep isolation well may be included to isolate the device well from the substrate. The deep isolation well may be a first polarity type doped well. As for the transistor, spacer units and elevated S/D regions, they are the same as described in FIGS. 2a-d.

FIG. 2e shows a simplified 3-dimensional (3D) view of an embodiment of a junctionless transistor 200. The transistor, for example, is disposed on a substrate (not shown). In one embodiment, the transistor is disposed on a COI substrate, such as a SOI substrate. In another embodiment, the transistor is disposed on bulk substrate. In the case that the transistor is disposed on the bulk substrate, a well is formed under the S/D regions and channel. For example, the S/D regions and the channel are n-type while the well formed under the S/D regions and channel is p-type. The transistor includes a body 213 disposed on the substrate. In the case of a SOI substrate, the body is formed by patterning the surface substrate of the COI substrate to form the body. The buried oxide (BOX) (not shown) separates the body from the bulk substrate. The transistor body, for example, is a nanowire or FinFET body.

A gate 250 is disposed over the substrate. The gate, for example, traverses the transistor body. In one embodiment, the gate electrode 254 traverses the body and a gate dielectric 252 surrounds the transistor body below the gate. The gate electrode may be a polysilicon gate electrode and the gate dielectric may be a thermal oxide gate dielectric. Other types of gates, such as metal gates may also be useful. The gate electrode is isolated from the bulk substrate by the BOX.

First and second S/D regions 242 and 244 disposed in the transistor body adjacent to sides of the gate. The S/D regions may include pad S/D regions for accommodating contacts. In the case of a junctionless transistor, the body, including the S/D regions and the channel under the gate, has the same dopant type. For example, the S/D regions and the channel may be doped with first polarity type dopants with the same dopant concentration. For example, no dopant gradient exists between the S/D regions and the channel. In some embodiments, a dopant gradient profile may be formed between the S/D regions and the channel. For example, the S/D regions may be heavily n-doped while the channel may be lightly or intermediately n-doped. The S/D regions and channel may be heavily doped with first polarity type dopants. In some cases, the transistor body may be heavily doped with first polarity type dopants, serving as S/D regions and the channel. The S/D regions and channel may be heavily doped n-type regions for a n-type junctionless transistor. Doping the S/D regions and channel with other dopant concentrations or dopant types may also be useful. In one embodiment, the gate electrode is heavily doped with second polarity type dopants, which is the opposite in polarity than the first polarity type dopants of the transistor body. In one embodiment, the cross-section of the transistor body under the gate should be sufficiently small so that the gate can deplete the heavily doped channel completely.

In the case of a finFET, it is similar to the junctionless transistor. A finFET may include a fin body which serves as a transistor. The fin body, for example, may be formed by patterning a surface substrate of a COI substrate, such as a SOI substrate. The fin body is isolated from the bulk substrate by the BOX. A gate traverses the fin body with the S/D regions and channel. In another embodiment, the fin body is disposed on bulk substrate. In the case that the fin body is disposed on the bulk substrate, a well is formed under the S/D regions and channel. For example, the S/D regions and the channel are n-type while the well formed under the S/D regions and channel is p-type. However, unlike the transistor body of the junctionless transistor, the fin body has a larger cross section and includes first and second S/D regions heavily doped with first polarity type dopants and a channel doped with second polarity type dopants.

In either case, the junctionless transistor and finFET are configured with spacer units, such as those described in FIGS. 2a-2d. For example, spacer units with ferroelectric spacers or spacer liners are provided. For example, the spacer units are separated form gate sidewalls of a junctionless transistor or a finFET by a dielectric liner such as an oxide liner.

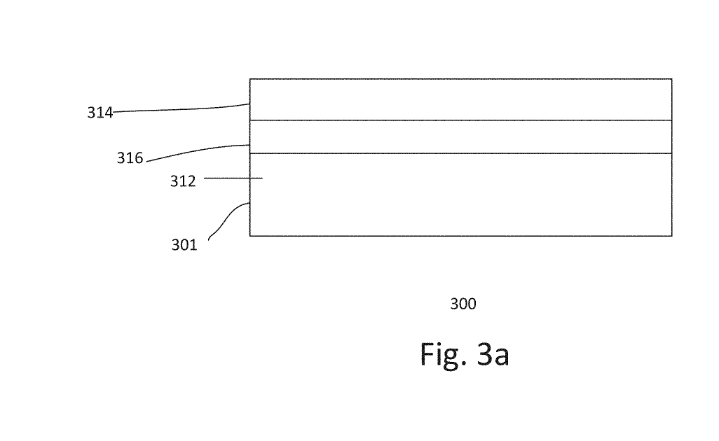

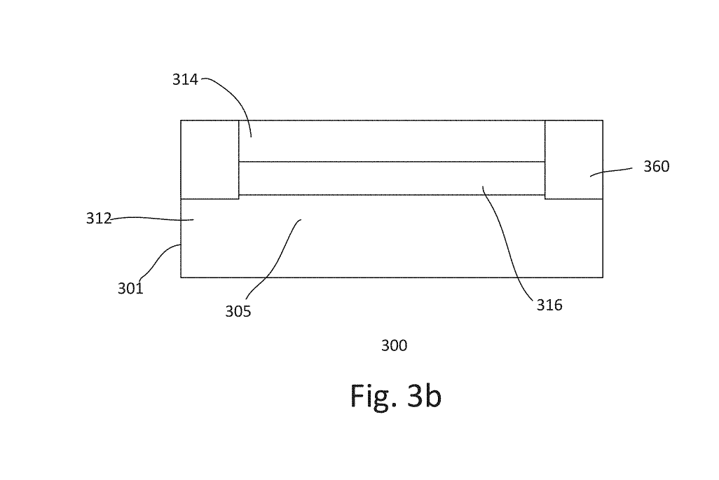

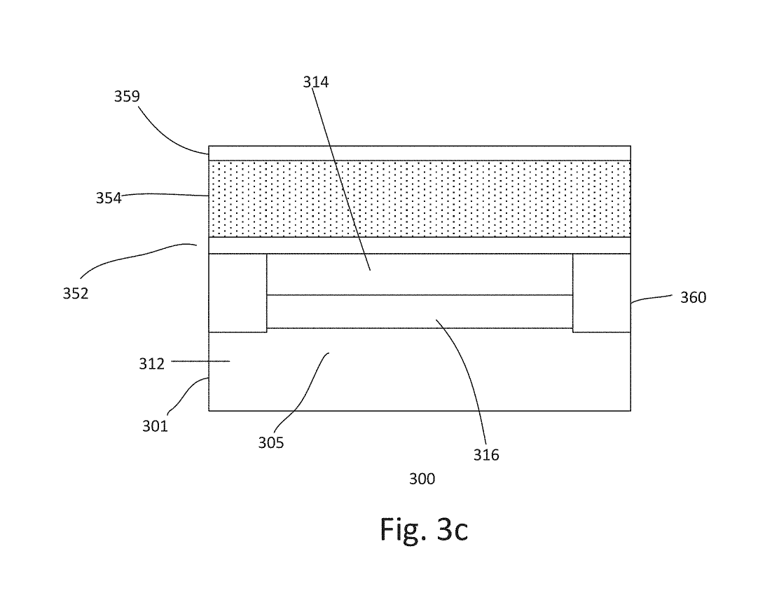

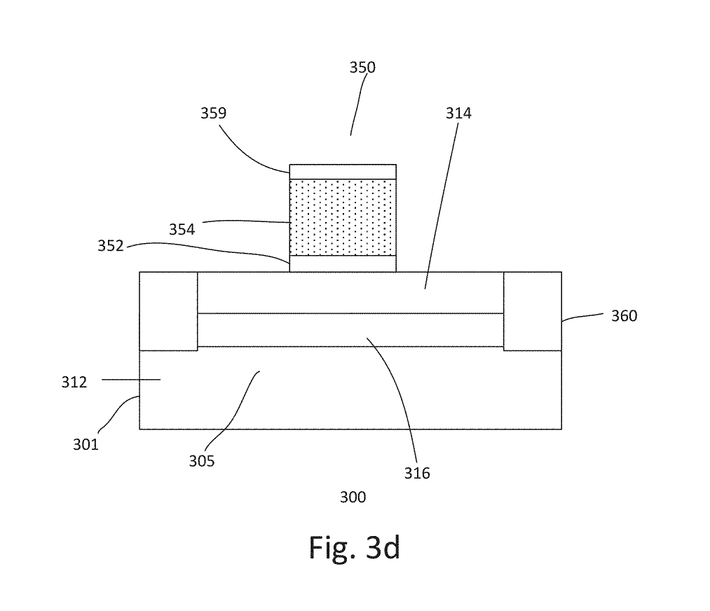

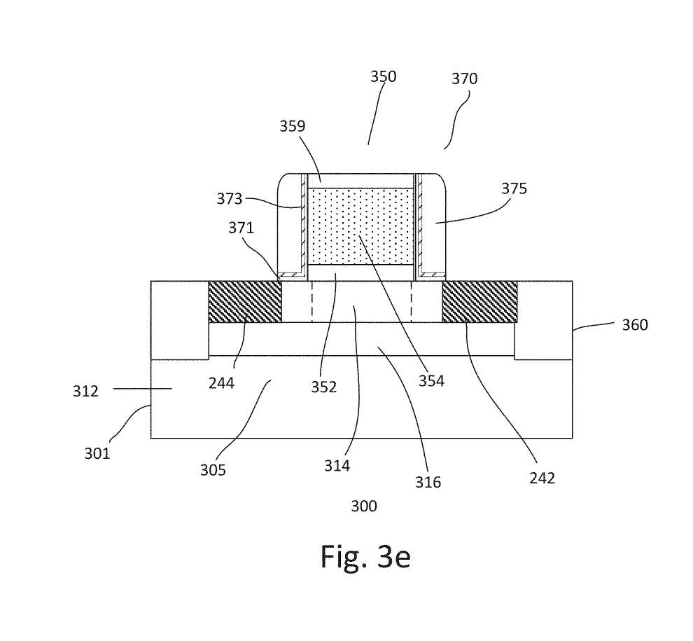

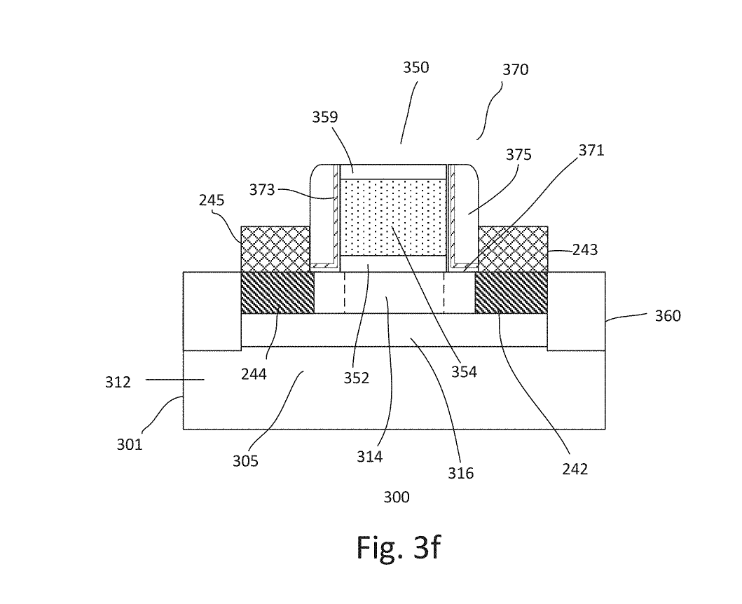

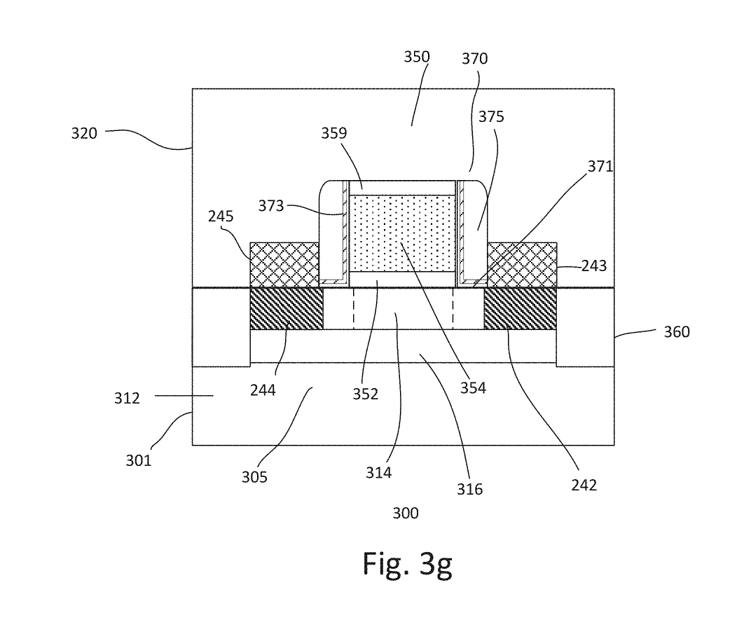

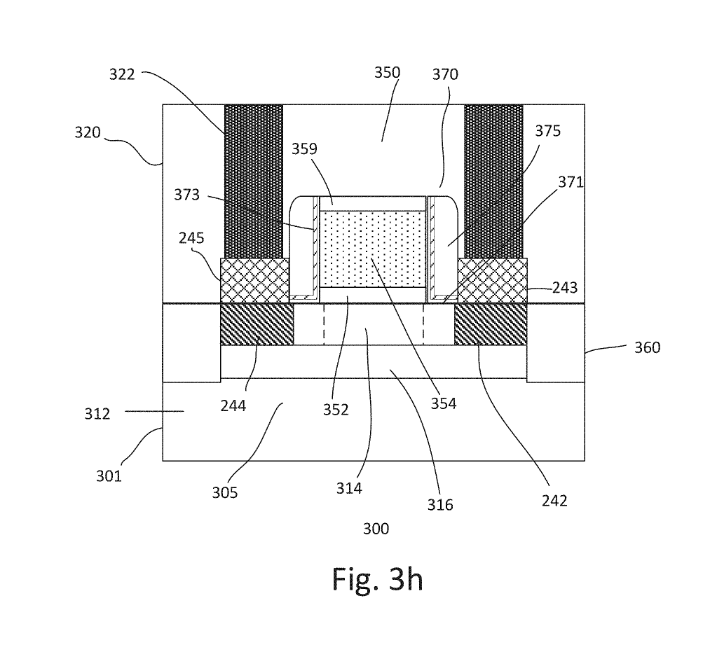

FIGS. 3a-h show cross-sectional views of an embodiment of a process for forming a device 300. The device, for example, is similar to that described in FIG. 1, and FIGS. 2a-d. Common elements may not be described or described in detail.

Referring to FIG. 3a, a substrate 301 is provided. The substrate, in one embodiment, is a COI substrate, such as a SOI substrate. The COI substrate includes a buried oxide layer 316 disposed between bulk and surface crystalline layers 312 and 314. Other types of substrates or wafers may also be useful. For example, the substrate may be bulk semiconductor substrate, such as silicon. The substrate may be doped. For example, the substrate can be lightly doped with p-type dopants. Providing a substrate with other types of dopants or dopant concentrations as well as an undoped substrate, may also be useful.

The substrate, as shown in FIG. 3b, is prepared with a device region (cell region) in which a transistor is formed. An isolation region 360 may be formed in the substrate. The isolation regions, for example, are STI regions. Other types of isolation regions may also be formed. A STI region surrounds a device region. Various processes can be employed to form the STI regions. For example, the substrate can be etched using etch and mask techniques to form isolation trenches which are then filled with dielectric materials such as silicon oxide by chemical vapor deposition (CVD). Chemical mechanical polishing (CMP) can be performed to remove excess oxide and to provide a planar substrate top surface. Other processes or materials may also be used to form the STIs. The depth of the STIs is slightly below the depth of the buried oxide layer.

A device well 305 is formed in the cell region. In one embodiment, the device well includes second polarity type dopants for a first polarity type transistor. The device well may be a lightly or intermediately doped second polarity type doped cell well. The cell well, in one embodiment, extends the depth of the surface substrate. The device well may be formed by implanting second polarity type dopants. An implant mask may be used to implant the second polarity type dopants. For example, the implant mask exposes the cell region in which dopants are to be implanted. An anneal is performed after forming the device wells. The anneal activates the dopants. As described, the process is for preparing the device region. Preparing other device regions may also be useful. Isolation regions may be formed to isolate the different regions. Implants may be performed to form the device wells. Separate implant processes may be employed to form differently doped or different types of device wells.

Referring to FIG. 3c, gate layers of the gate of the transistor are formed on the substrate. For example, a gate dielectric 352 and a gate electrode 354 are formed on the substrate. The gate dielectric may be a silicon oxide layer formed by thermal oxidation while the gate electrode may be a polysilicon layer formed by CVD. Other types of gate layers or processes may also be useful. In one embodiment, a hard mask layer 359 may be formed over the gate electrode layer. The hard mask layer is a dielectric layer, such as silicon oxide. Other types of hard mask layers may also be useful

In FIG. 3d, the gate layers, including the hard mask layer, are patterned to form a gate 350. To form the gate, mask and etch techniques may be used. For example, a soft mask, such as a photoresist mask, may be formed over the hard mask layer. An exposure source may selectively expose the photoresist layer through a reticle containing the desired pattern. After selectively exposing the photoresist layer, it is developed to form openings corresponding to the location where the gate layers are to be removed. To improve lithographic resolution, an anti-reflective coating (ARC) may be used below the photoresist layer. In other embodiments, the gate layers may be patterned using a resist mask without a hard mask.

The patterned mask layer serves as an etch mask for a subsequent etch process. For example, the etch transfers the pattern of the mask to the gate layers. The etch removes the gate layers unprotected by the mask, exposing the substrate. The etch, for example, may be an anisotropic etch, such as reactive ion etch (RIE). Other types of etch processes may also be useful. In one embodiment, an RIE is employed to pattern the gate layers to form the gate stack. After pattern the gate layers, the etch mask is removed, for example, by ashing. Other techniques for removing the etch mask may also be useful.

As shown in FIG. 3e, LD extension regions 242 and 244 and spacer units 370 are formed. Forming the spacer units include forming a first spacer liner 371, a second spacer liner 373 and a spacer layer 375. The first spacer liner may be a silicon oxide liner, the second spacer liner may be a ferroelectric liner and the spacer layer may be a silicon oxide layer. Other types of spacer layers, such as silicon nitride or oxynitride, may also be useful. The first oxide liner may be formed by CVD or in situ stream generation (ISSG), the ferroelectric liner may be formed by atomic layer deposition (ALD) or physical vapor deposition (PVD) and the spacer layer may be formed by CVD. Other types of spacer liners and layers or processes may also be useful. An etch, an anisotropic etch, such as ME, may be performed to form the spacer units.

As for the LD extension regions 242 and 244, they are formed by ion implantation process. The LD extension regions, for example, may be formed by implanting first polarity type dopants into surface substrate in the device regions. In one embodiment, the LD extension ion implantation process is performed after forming the spacer units. The LD extension regions are aligned with about an outer edge of the spacer units. For example, the adjacent edges of the LD extension regions may extend slightly under the spacer units.

In other embodiments, the LD extension ion implantation process is performed prior to forming the spacer units. In such case, the LD extension regions may be aligned with about the sidewalls of the gate. For example, the adjacent edges of the LD extension regions may extend slightly under the gate sidewalls, as indicated by the dotted lines. In yet other embodiments, no LD extension regions are formed, for example, in the case of a junctionless transistor.

Referring to FIG. 3f, elevated S/D regions 243 and 245 are formed above the LD regions. To form elevated SD regions, epitaxial layers are formed over the device region over the LD extension regions. In one embodiment, the elevated S/D regions are formed by selective epitaxial growth (SEG). The elevated S/D regions may be doped by in situ doping. Alternatively, the elevated S/D regions may be doped by an ion implantation process.

Metal silicide contacts may be formed on terminals or contact regions. For example, metal silicide contacts may be provided on exposed top surface of the gate electrode and exposed S/D regions. In the case that a hard mask is disposed on the gate electrode, it may be patterned to form openings to expose the gate electrode for gate contacts. Metal silicide contacts may also be formed in other contact regions for other devices. The silicide contacts, for example, may be nickel-based silicide contacts. Other types of metal silicide contacts may also be useful. For example, the metal silicide contact may be nickel silicide (NiSi). The silicide contacts may be about 50-300 Å thick. Other thickness of silicide contacts may also be useful. The silicide contacts may be employed to reduce contact resistance and facilitate contact to the back-end-of-line metal interconnects.

To form the silicide contacts, a metal layer is deposited on the surface of the substrate. The metal layer, for example, may be nickel or an alloy thereof. Other types of metallic layers, such as cobalt, or alloys thereof, may also be used. The metal layer can be formed by physical vapor deposition (PVD). Other types of metal elements that can be formed by other types of processes can also be useful.

An anneal may be performed. The anneal diffuses the metal dopants into the active substrate, forming a silicide layer. Excess metal not used in the silicidation of the active surface is removed by, for example, a wet removal process. For example, unreacted metal material is removed selectively to form the silicide contacts.

Referring to FIG. 3g, a first dielectric layer 320 is formed on the substrate. The dielectric layer covers the substrate and gates. The dielectric layer may be a silicon oxide dielectric layer formed by CVD. A planarizing process, such as CMP, is performed to form a planar top surface over the gate stack. The first dielectric layer serves as a first inter-layer dielectric layer of the back-end-of-line (BEOL) dielectric.

In FIG. 3h, contacts 322 are formed to contact regions on the substrate. The contacts may be formed by etching via openings in the first inter-layer dielectric layer, filling it with a conductive material, such as tungsten. Other types of conductive materials may also be useful. Excess conductive material may be removed by, for example CMP.

Thereafter, additional BEOL processing is performed to complete forming the device. Such processes may include, for example, additional ILD levels, final passivation, dicing, packaging and testing. Other or additional processes may also be included.

In other embodiments, the process may be modified to form spacer units as described in FIGS. 2c-d. For example, the process may be modified to form an oxide spacer liner and a ferroelectric spacer layer. The spacer liner and ferroelectric spacer layer are etched by, for example, RIE to form spacer units, each having an oxide liner and a ferroelectric spacer. A recess etch is performed to recess the ferroelectric spacer layer below the top of the gate but above the elevated S/D layers. The spacer units may be formed prior or after LD extension regions.

In yet other embodiments, the process may be modified to form the transistor on a bulk semiconductor substrate, such as a silicon substrate. For example, the device region is defined on a bulk substrate, which includes forming STI region and device well. A deep isolation well may be formed prior to forming the STI region to isolate the device well from the substrate. For example, the isolation well is a first polarity type well and is deeper than the device well. After defining the device region, the process processes as discussed in forming the transistor.

As described, the process forms a gate first transistor. For example, the gates are formed prior to forming S/D regions. In other embodiment, the process may be modified to form a gate last transistor. In gate last transistor, the process is similar to that described up to forming metal silicide contacts using a dummy gate, similar to that of FIG. 3f. In such case, no metal silicide contact is formed on the dummy gate. For example, a hard mask may be disposed on the dummy gate to prevent formation of metal silicide contacts.

A dielectric layer is formed on the substrate covering the gate, as described in FIG. 3h. The dielectric layer may be planarized by, for example, CMP to expose the gate. The CMP forms a planar surface between the top of the gate and the dielectric layer. In some cases, metal silicide contacts may be disposed on the dummy gate. In such case, the CMP or an etch process may remove the metal silicide contact to expose the gate.

An etch is performed to remove the dummy gate using an etch mask, such as photoresist. The etch, for example, may be an anisotropic etch, such as ME. Removal of the dummy gate, including the gate electrode and gate dielectric, forms a gate trench opening in the dielectric layer in the gate region. A high k dielectric is formed on the substrate. The high k dielectric lines the dielectric layer, including the gate trench opening. A metal gate layer is formed on the substrate, filling the trench opening lined with the high k dielectric layer. A planarization, such CMP, removes excess high k dielectric layer and metal gate layer from the surface of the dielectric layer. This forms a metal gate in the trench opening.

In other embodiments, the process may be employed to form a junctionless transistor. In the case of a junctionlesss transistor, a surface substrate of a COI substrate is patterned to form a nanowire body of the junctionless transistor. The nanowire body, for example, is disposed on the BOX. After the nanowire body is formed, it is doped with first polarity type dopants. For example, an implant may be employed to form a first polarity type heavily doped body. In other embodiments, the surface substrate may be doped prior to forming the transistor body.

The process continues to form gate layers, such as a gate dielectric layer and a gate electrode layer, as previously described. The gate electrode layer, such as polysilicon, may be heavily doped with second polarity type dopants. Doping the gate electrode layer may be achieved by ion implantation or in-situ doping. The gate layers are patterned to form a gate which traverses the transistor body with the S/D regions and channel which are heavily doped with first polarity type dopants.

The process proceeds to form spacer units with ferroelectric liner or spacer, as previously described in FIGS. 2a-2e and 3a-3h. The process may continue to form BEOL dielectric and interconnects as well as other processes to complete forming the device.

In yet other embodiments, the process may be employed to form a finFET. In the case of a finFET, a surface substrate of a COI substrate is pattered to form a fin body. The fin body, for example, is disposed on the BOX. After the fin body is formed, it is doped with second polarity type dopants to serve as a channel. For example, an implant may be employed to form a second polarity type well which serves as a channel of the finFET. In other embodiments, the surface substrate may be doped prior to forming the fin body.

The process continues to form gate layers, such as a gate dielectric layer and a gate electrode layer, as previously described. The gate layers are patterned to form a gate which traverses the fin body. The process may continue to form LD extension regions, spacer units, S/D regions and metal silicide contacts, as previously described. In some embodiments, the gate may be a dummy gate. In such case, a metal gate may be formed after removing the dummy gate, as previously described. The process may continue to form a BEOL dielectric and interconnects as well as other processes to complete forming the device.

The present disclosure may be embodied in other specific forms without departing from the spirit or essential characteristics thereof. The foregoing embodiments, therefore, are to be considered in all respects illustrative rather than limiting the invention described herein. Scope of the disclosure is thus indicated by the appended claims, rather than by the foregoing description, and all changes that come within the meaning and range of equivalency of the claims are intended to be embraced therein.

1-11. (canceled)

12. A method of forming a device comprising:
forming a substrate with a device region;
forming a gate and source/drain (S/D) regions in the device region; and
forming one or more spacer units on sidewalls of the gate, wherein forming the one or more spacer units comprises
forming a first dielectric spacer liner deposited on the sidewalls of the gate, and
forming a second dielectric spacer liner or layer on the first dielectric spacer liner, wherein the second dielectric spacer liner or layer comprises a second negative capacitance spacer liner or layer coupled with the S/D regions, the negative capacitance spacer liner or layer enhances gate-to-S/D region coupling between the gate and the S/D regions.

13. The method of claim 12 wherein forming the first dielectric liner comprises forming a first L-shaped oxide liner, wherein the first L-shaped oxide liner is formed by chemical vapor deposition (CVD) or in situ stream generation (ISSG).

14. The method of claim 13 wherein forming the second negative capacitance spacer liner or layer comprises forming a second L-shaped ferroelectric liner, wherein the second L-shaped ferroelectric liner is formed by atomic layer deposition (ALD) or physical vapor deposition (PVD).

15. The method of claim 14 wherein forming the one or more spacer units further comprise forming a dielectric spacer, wherein the dielectric spacer is disposed in a space created by the first L-shaped oxide liner and the second L-shaped ferroelectric liner.

16. The method of claim 13 wherein forming the second negative capacitance spacer liner or layer comprises forming a second ferroelectric layer, wherein the second ferroelectric layer extends at least a partial height of the gate and is formed by atomic layer deposition (ALD) or physical vapor deposition (PVD).

17. The method of claim 16 further comprises forming contacts on the substrate, wherein the second ferroelectric layer enhances gate-to-contacts coupling between the gate and the contacts.

18. The method of claim 12 wherein forming the S/D regions of the gate comprises forming overlapping S/D extensions and elevated S/D regions, wherein edges of the overlapping S/D extensions extend slightly under the transistor.

19. The method of claim 12 wherein forming the S/D regions of the gate comprises underlapping S/D extensions and elevated S/D regions, wherein edges of the underlapping S/D extensions extend slightly under the one or more spacer units.

20. The method of claim 12 wherein forming the S/D regions comprises forming epitaxial S/D layers doped with first polarity type dopants.

21. The method of claim 14 wherein the second L-shaped ferroelectric liner comprises hafnium-silicon oxide (HfSiOₓ).

22. The method of claim 16 wherein the second ferroelectric layer comprises hafnium-silicon oxide (HfSiOₓ).

23. A method of forming a device comprising:
forming a substrate with a device region;
forming a gate and source/drain (S/D) regions in the device region; and
forming a composite spacer on the gate sidewalls, wherein forming the composite spacer comprises forming a negative capacitance spacer liner or layer coupled with the S/D regions, the negative capacitance spacer liner or layer enhances gate-to-S/D region coupling between the gate and the S/D regions.

24. The method of claim 23 wherein forming the composite spacer further comprises forming a dielectric liner disposed between the negative capacitance spacer liner or layer and the gate sidewalls.

25. The method of claim 24 wherein forming the dielectric liner comprises forming a first L-shaped oxide liner.

26. The method of claim 25 wherein forming the negative capacitance spacer liner or layer comprises forming a second L-shaped ferroelectric liner.

27. The method of claim 26 wherein forming the composite spacer further comprises forming a dielectric spacer disposed in a space created by the first L-shaped oxide liner and the second L-shaped ferroelectric liner.

28. The method of claim 25 wherein forming the negative capacitance spacer liner or layer comprises forming a second ferroelectric layer, wherein the second ferroelectric layer extends at least a partial height of the gate.

29. The method of claim 28 further comprises forming contacts on the substrate, wherein the second ferroelectric layer enhances gate-to-contacts coupling between the gate and the contacts.

30. The method of claim 23 wherein forming the S/D regions of the gate comprises forming overlapping S/D extensions and elevated S/D regions.

31. The method of claim 23 wherein forming the S/D regions of the gate comprises forming underlapping S/D extensions and elevated S/D regions.
